(19) United States
(12) Patent Application Publication
(10) Pub. No.: US 2014/0295202 A1
(43) Pub. Date: Oct. 2, 2014

(54) COMPOSITE MOLDED CASING

(71) Applicant: NISHOKU TECHNOLOGY INC., New Taipei City (TW)

(72) Inventors: Li-Hao LU, New Taipei City (TW); Chien-Sheng TSAI, New Taipei City (TW)

(73) Assignee: NISHOKU TECHNOLOGY INC., New Taipei City (TW)

(21) Appl. No.: 14/098,975

(22) Filed: Dec. 6, 2013

(30) Foreign Application Priority Data
Mar. 26, 2013 (TW) 102205558

(51) Int. Cl. H05K 5/04; B29C 45/16; H05K 5/02; B29C 37/00

(52) U.S. Cl. CPC H05K 5/04; B29C 37/0028; B29C 45/1679; H05K 5/02
USPC 428/595; 428/35.7; 428/35.8

(57) ABSTRACT

The present invention discloses a composite molded casing, which comprises a casing body having a mold line and a decorative layer coated on the surface of the casing body to cover the mold line. The present invention exempts the composite molded casing from complicated secondary machining processes (such as processes of grinding and polishing) and thus indirectly reduces the fabrication cost of molds and promotes the yield of products. Further, the present invention uses an IMF technology to fabricate the decorative layer, not only completely covering the mold line but also overcoming the problem of color difference likely to occur in the conventional injection-molded plastic products. Therefore, the present invention can exempt the composite molded casing from complicated post-fabrication processes, such as processes of paint spraying, printing, electroplating, photoelectric engraving, etc.

This application claims priority for Taiwan patent application no. 102205558 filed on Mar. 26, 2013, the content of which is incorporated by reference in its entirety.

### BACKGROUND OF THE INVENTION

1. Field of the Invention

The present invention relates to a molded casing, particularly to a composite molded casing.

2. Description of the Related Art

The mold is regarded as the mother of industrial products, able to mass-fabricate products in low cost, high reproducibility and high efficiency. Almost all industrial products are mass-fabricated with molds.

Molds may be categorized into stamping molds, injection molds, die casting molds, forging molds, drilling jigs, fixtures, etc. However, they function similarly, using the mold cavities to shape materials having plasticity or flowability into specified forms.

Refer to FIG. 1 and FIG. 2 respectively showing the conventional fabrication method of a molded product and the appearance of the conventional molded product. In the conventional molding fabrication technology, a mold 10 is split into an upper mold 12 and a lower mold 14, which are installed on a mold base 16 and cooperate to shape the material into a molded product 18 having a specified form, such as the parts of TV, telephones, laundry machines, airplanes, automobiles, watches, clocks, computers, computer peripherals, weapons, military appliances, etc.

As shown in FIG. 1 and FIG. 2, the upper mold 12 and the lower mold 14 are assembled together along the interface 20. Thus, a tool mark or a joint line will be formed on the molded product 18 along the interface 20, and both of them are generically called the mold line 22 in the specification. The mold line 22 would degrade the appearance of the molded product 18. Therefore, various secondary machining processes, such as processes of grinding and polishing, are used to improve the appearance of the molded product 18. The secondary machining processes are complicated, time-consuming and laborious, increasing fabrication cost and lowering the yield.

Besides, the color of the conventional injection-molded plastic products is hard to control and likely to depart from the designed color. Thus, the conventional injection-molded plastic products need to be further treated by post-fabrication processes, such as processes of paint spraying, printing, electroplating, photoelectric engraving, etc.

Accordingly, the Inventor studied, researched and analyzed the abovementioned problems and finally developed a composite molded casing to overcome the abovementioned problems.

### SUMMARY OF THE INVENTION

The primary objective of the present invention is to provide a composite molded casing, wherein a decorative layer is coated on the surface of the casing body to cover the mold line, whereby the composite molded casing is exempted from various secondary machining processes, wherefore the fabrication cost of molds is indirectly reduced and the yield of molded products is promoted.

To achieve the abovementioned objective, the present invention proposes a composite molded casing, which comprises a casing body having a mold line and a decorative layer coated on the surface of the casing body to cover the mold line.

Below, the embodiments are described in detail in cooperation with the attached drawings to make easily understood the objectives, technical contents, characteristics and accomplishments of the present invention.

### BRIEF DESCRIPTION OF THE DRAWINGS

FIG. 1 schematically shows the conventional fabrication method of a molded product;

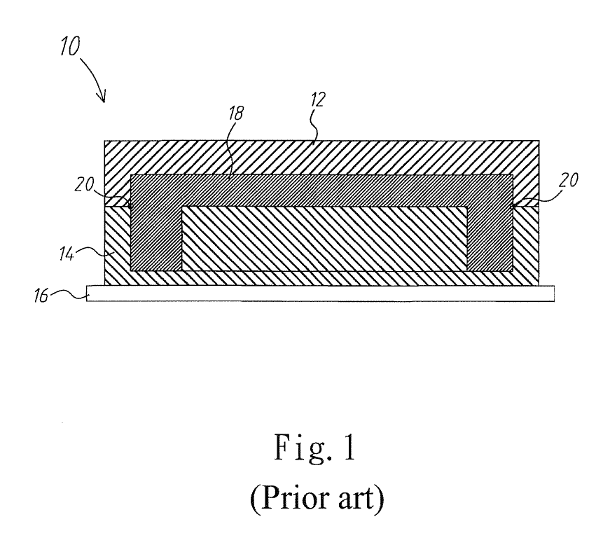

FIG. 2 schematically shows the appearance of a conventional molded product;

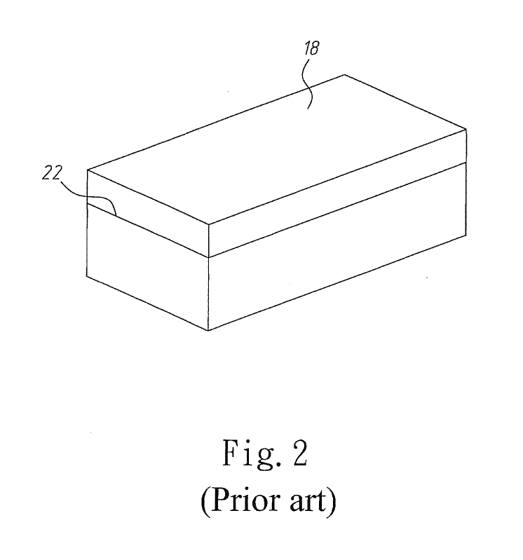

FIG. 3 schematically shows the appearance a composite molded casing according to a first embodiment of the present invention;

FIG. 4 schematically shows the section of a composite molded casing according to the first embodiment of the present invention;

FIG. 5 schematically shows the fabrication method of the casing body of a composite molded casing according to the first embodiment of the present invention; and

FIG. 6 schematically shows the section of a composite molded casing according to a second embodiment of the present invention.

### DETAILED DESCRIPTION OF THE INVENTION

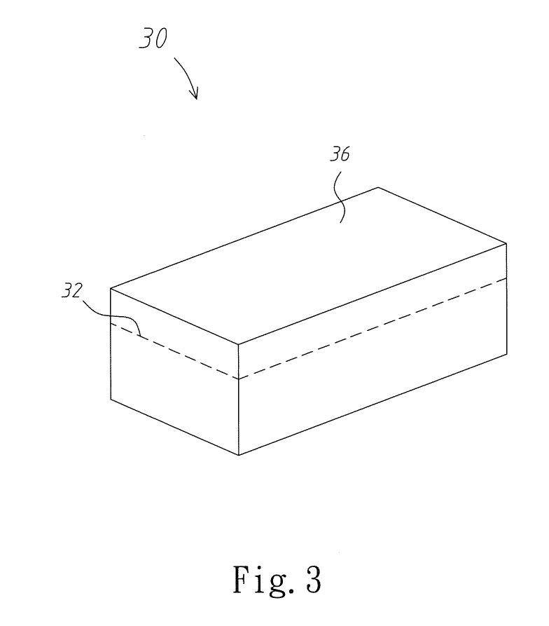

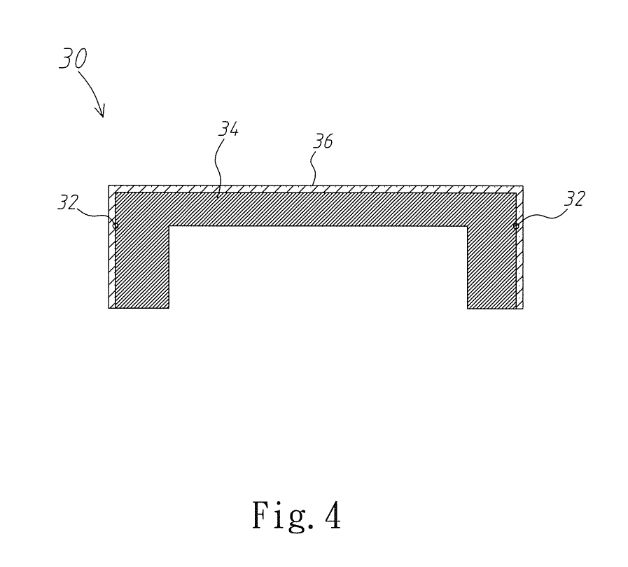

Refer to FIG. 3 and FIG. 4 diagrams respectively schematically showing the appearance and section of a composite molded casing according to a first embodiment of the present invention. The composite molded casing 30 of the present invention comprises a casing body 34 having a mold line 32 and a decorative layer 36 coated on the external surface of the casing body 34 to cover the mold line 32.

In the present invention, the casing body 34 is made of a plastic material or a metallic material; the decorative layer 36 is also made of a plastic material or a metallic material. The metallic material is an aluminum alloy, a metallic glass or a ferro-aluminum alloy.

In the present invention, the casing body 34 is fabricated with a stamping mold, an injection mold, a die-casting mold, a forging mold, a drilling jig or a fixture, and the mold line 32 is formed in fabrication.

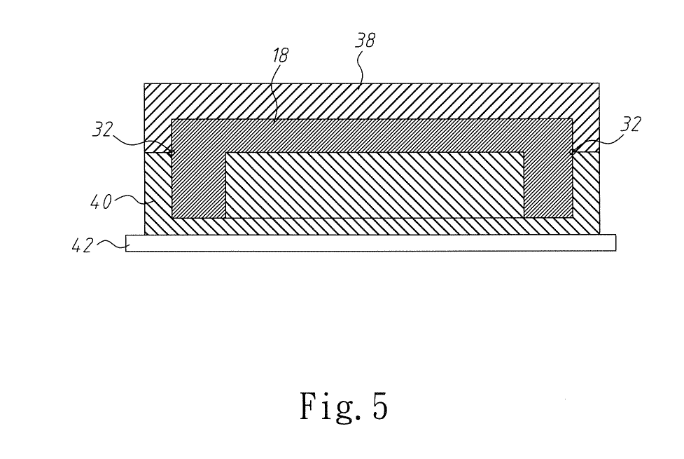

In order to fully disclose the present invention in the specification, a plastic casing fabricated with an injection mold is used to exemplify and demonstrate the present invention to enable the persons skilled in the art to understand, make, and use the present invention. Refer to FIG. 5 schematically showing the fabrication method of the casing body of a composite molded casing according to the first embodiment of the present invention. In the present invention, an upper mold 38 and a lower mold 40 are installed on a mold base 42 and cooperate to shape the material into a casing body 34 having a mold line 32. In the present invention, the casing body 34 can be used to fabricate a casing of a mobile phone, a casing of a household appliance, a casing of an electronic device, or an automobile part.

Refer to FIG. 4 again. The casing body 34 and the decorative layer 36 are made of an identical material or respectively made of different materials. The decorative layer 36 is fabricated with an IMF (In-Mold Film) technology. The decorative layer 36 has a thickness of over 200 μm so as to completely cover the mold line 32.

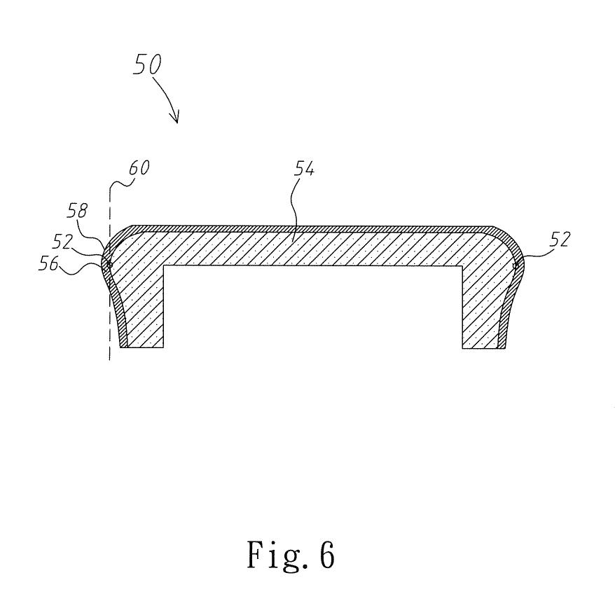

The first embodiment disclosed hereinbefore is only to exemplify the present invention but not to limit the scope of the present invention. Refer to FIG. 6 a diagram schematically showing a composite molded casing according to a second embodiment of the present invention, and refer to FIG. 4 again. The composite molded casing 50, the mold line 52, the casing body 54 and the decorative layer 56 of the second embodiment are respectively identical to the composite molded casing 30, the mold line 32, the casing body 34 and the decorative layer 36 of the first embodiment, and will not repeat herein. However, the second embodiment is different from the first embodiment in that the casing body 54 can have an arbitrary shape. For example, one lateral of the casing body 54 is molded to have an arc shape 58; the mold line 52 is at the apex of a section 60 of the casing body 54; the decorative layer 56 covers the mold line 52 at the apex of the section 60.

In conclusion, the present invention proposes a composite molded casing, wherein a decorative layer is coated on the surface of the casing body to cover the mold line, whereby the composite molded casing is exempted from complicated secondary machining processes, such as processes of grinding and polishing, wherefore the fabrication cost of the molds is indirectly reduced and the yield of products is promoted. Nowadays, the manufacturers trend to design different structures and appearances for electronic products, especially consumer electronic products, to meet the requirement of individualization and the demand for different functions. The decorative layer of the present invention is particularly suitable to fabricate a product having a metallic-textured appearance presenting modem sci-tech esthetics. Even though there are blisters on the surface of the casing body, the decorative layer of the present invention can also cover the blisters, providing an esthetic appearance for the composite molded casing and saving the money and labor spent in repairing the blisters and grinding the surface.

Further, the present invention uses an IMF technology to fabricate the decorative layer, not only completely covering the mold line but also overcoming the problem of color difference likely to occur in the conventional injection-molded plastic products. Therefore, the present invention can exempt the composite molded casing from complicated post-fabrication processes, such as processes of paint spraying, printing, electroplating, photoelectric engraving, etc.

The embodiments have been described above to demonstrate the characteristics of the present invention and enable the persons skilled in the art to understand, make, and use the present invention. However, these embodiments are only to exemplify the present invention but not to limit the scope of the present invention. Any equivalent modification or variation according to the structure, shape, characteristic or spirit of the present invention is to be also included within the scope of the present invention.

What is claimed is:

1. A composite molded casing at least comprising
a casing body having a mold line; and
a decorative layer coated on surface of said casing body and covering said mold line.

2. The composite molded casing according to claim 1, wherein said casing body is made of a plastic material or a metallic material.

3. The composite molded casing according to claim 2, wherein said decorative layer is made of a plastic material or a metallic material.

4. The composite molded casing according to claim 3, wherein said metallic material is selected from a group consisting of aluminum alloys, metallic glasses, and ferro-aluminum alloys.

5. The composite molded casing according to claim 3, wherein said casing body and said decorative layer are made of an identical material.

6. The composite molded casing according to claim 3, wherein said casing body and said decorative layer are respectively made of different materials.

7. The composite molded casing according to claim 1, wherein one lateral of said casing body is molded to have an arc shape, and said mold line is at an apex of a section of said casing body.

8. The composite molded casing according to claim 3, wherein one lateral of said casing body is molded to have an arc shape, and said mold line is at an apex of a section of said casing body.

9. The composite molded casing according to claim 1, wherein said decorative layer is fabricated with an IMF (In-Mold Film) technology.

10. The composite molded casing according to claim 3, wherein said decorative layer is fabricated with an IMF (In-Mold Film) technology.

11. The composite molded casing according to claim 1, wherein said decorative layer has a thickness of over 200 μm.

12. The composite molded casing according to claim 3, wherein said decorative layer has a thickness of over 200 μm.

13. The composite molded casing according to claim 1, wherein a stamping mold, an injection mold, a die-casting mold, a forging mold, a drilling jig or a fixture is used to fabricate said casing body with said mold line formed thereon.

14. The composite molded casing according to claim 1, wherein said casing body is used to fabricate a casing of a mobile phone, a casing of a household appliance, a casing of an electronic device, or an automobile part.
